(19) United States
(12) Patent Application Publication
(10) Pub. No.: US 2010/0264535 A1
(43) Pub. Date: Oct. 21, 2010

(54) INTEGRATED CIRCUIT PACKAGE ASSEMBLY AND SUBSTRATE PROCESSING METHOD

(75) Inventor: Ching-Yao Fu, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/467,313

(22) Filed: May 18, 2009

(30) Foreign Application Priority Data
Apr. 16, 2009 (CN) 200910106836.9

(51) Int. Cl. H01L 23/52; H01L 23/48

(52) U.S. Cl. 257/698; 257/741; 257/E23.141; 257/E23.01

(57) ABSTRACT

An integrated circuit (IC) package assembly includes a substrate and an IC. The substrate defines a plurality of vias. Inner walls of the plurality of vias and surfaces of the substrate are coated with copper. The plurality of vias are filled with an adhesive. The copper coated on surfaces of the substrate among the plurality of vias are etched. The IC is fixed on the substrate by cohesion between the adhesive and the etched surfaces of the substrate.

### BACKGROUND

1. Technical Field

The present disclosure relates to semiconductor packages, and more particularly to an integrated circuit (IC) package assembly and substrate processing method.

2. Description of Related Art

Due to rapid developments in electronic technology, electronic products have been drastically reduced in size, resulting in a desire for small size integrated circuits (ICs) applied in the electronic products. Accordingly, IC packages have been reduced in size.

FIG. 3 is a cross-sectional view of one such IC package assembly 100. The IC package assembly 100 includes a substrate 10, a bonding pad 30, and an IC 60. The bonding pad 30 is disposed on a surface of the substrate 10. The IC 60 is fixed on the bonding pad 30 by an adhesive 51.

However, the adhesive 51 has no cohesion with the substrate 10, so the adhesive 51 is prone to part from the bonding pad 30 when the IC package assembly 100 goes through a reflow procedure.

### BRIEF DESCRIPTION OF THE DRAWINGS

Many aspects of the embodiments can be better understood with references to the following drawings.

FIG. 1 is a cross-sectional view of one embodiment of an integrated circuit (IC) package assembly in accordance with the present disclosure.

FIG. 2 is a flowchart of one embodiment of an IC package substrate processing method in accordance with the present disclosure.

FIG. 3 is a cross-sectional view of an IC package assembly.

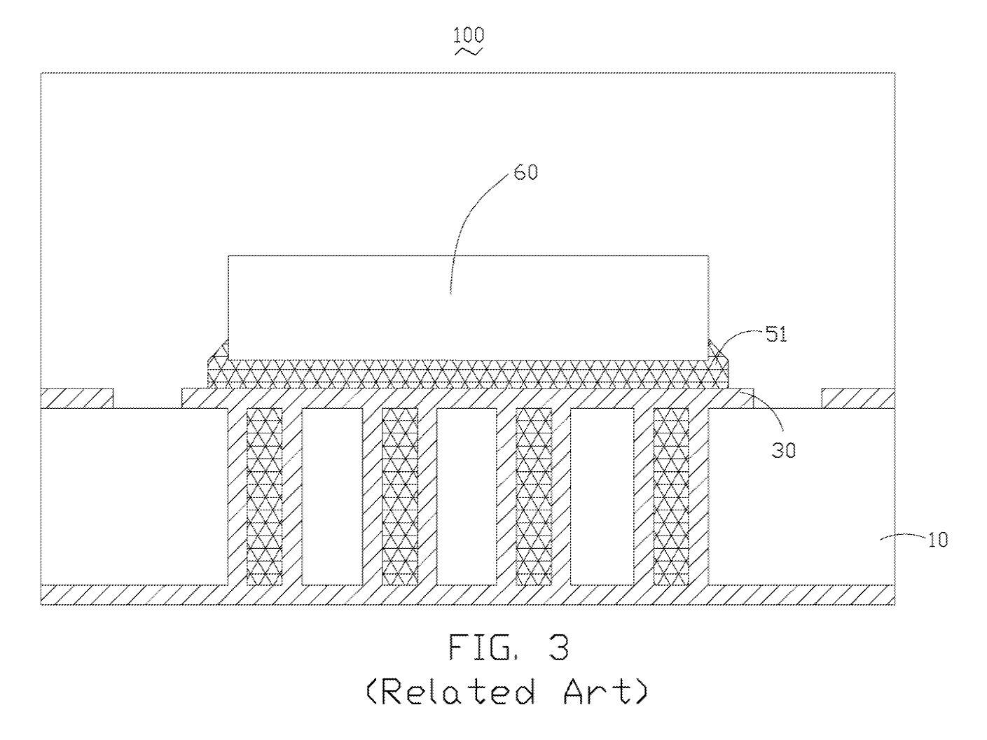

### DETAILED DESCRIPTION

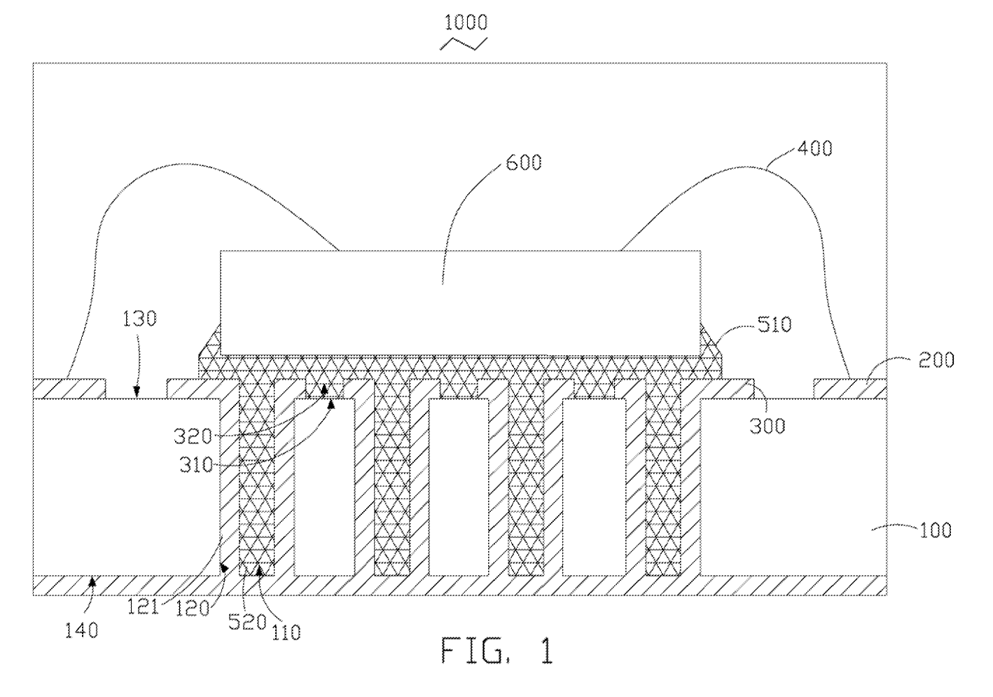

FIG. 1 is a cross-sectional view of one embodiment of an integrated circuit (IC) package assembly 1000 in accordance with the present disclosure. In one embodiment, the IC package assembly 1000 includes a substrate 100 and an IC 600. The substrate 100 is a printed circuit board, in one example, and defines a plurality of vias 110. Inner walls 120 of the vias 110 are coated with copper 121. The vias 110 are filled with an adhesive 520. A first surface 130 and a second surface 140 of the substrate 100 are coated with copper. Copper 320 coated on top surfaces 310 of the substrate 100 among the plurality of vias 110 are removed through a process, such as an etching process. The IC 600 is fixed on the substrate 100 by cohesion between the adhesive 510 and the etched surfaces 310 of the substrate 100 and surfaces of the IC 600. In one example, the adhesive 510 is an epoxy resin.

In one embodiment, surfaces of the substrate 100 that have been coated with copper but have not been etched are configured as golden fingers 200 and a bonding pad 300 with a plurality of clearances 320 to allow an increased contact area between the adhesive 510 and the substrate 100. The bonding pad 300 has substantially the same thickness as the plurality of golden fingers 200. Because of the clearances 320 of the bonding pad 300 being disposed among the plurality of vias 110, contact and cohesion between the adhesive 510 and the substrate 100 is increased. Therefore, heat stress of the adhesive 510 is reduced, and the adhesive 510 will not easily separate from the bonding pad 300. The bonding pad 300 and the copper 121 coated on the inner walls 120 of the vias 110 are sufficiently contacted with the adhesive 510, which improves heat dissipation of the IC 600.

The IC 600 is fixed on the bonding pad 300 by the adhesive 510, and connected to the plurality of golden fingers 200 via a plurality of bonding wires 400. A width and a length of the bonding pad 300 are greater than a width and a length of the IC 600, respectively. In this embodiment, the adhesive 510 is filled between the IC 600 and the bonding pad 300, and also filled in the clearances 320 defined by the bonding pad 300.

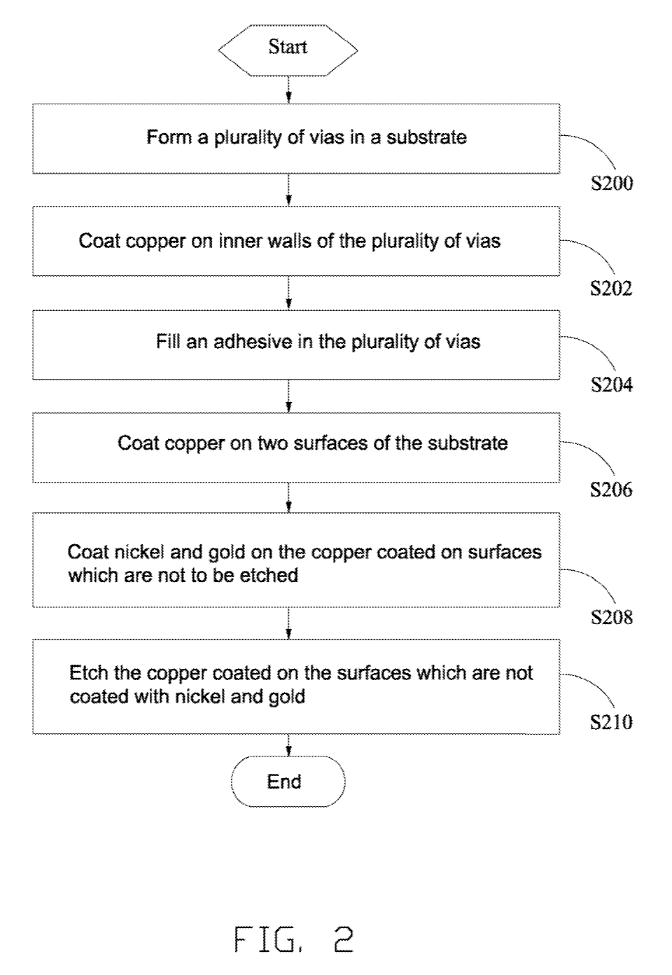

FIG. 2 is a flowchart of one embodiment of an IC package substrate processing method in accordance with the present disclosure. The IC package substrate processing method is operable to enhance cohesion between the IC 600 and the substrate 100.

In block S200, the plurality of vias 110 are formed in the substrate 100. In one example, the plurality of vias 110 are drilled in the substrate 100.

In block S202, copper 121 is coated on the inner walls 120 of the plurality of vias 110.

In block S204, the adhesive 520 is filled in the plurality of vias 110.

In block S206, copper is coated on the first surface 130 and the second surface 140 of the substrate 100.

In block S208, nickel and gold are coated on the copper coated on surfaces of the substrate 100 which are not to be etched.

In block S210, the copper coated on the surfaces of the substrate 100 which are not coated with nickel and gold are etched.

In one embodiment, the etched surfaces of the substrate 100 are provided to fixe the IC 600 by adhesive 510.

While various embodiments and methods of the present disclosure have been described above, it should be understood that they have been presented by way of example only and not by way of limitation. Thus the breadth and scope of the present disclosure should not be limited by the above-described embodiments, but should be defined only in accordance with the following claims and their equivalents.

What is claimed is:

1. An integrated circuit (IC) package assembly comprising:
a substrate defining a plurality of vias, inner walls of the plurality of vias and surfaces of the substrate being coated with copper, the plurality of vias being filled with an adhesive, the copper coated on surfaces of the substrate among the plurality of vias being etched; and
an IC fixed on the substrate by cohesion between the adhesive and the etched surfaces of the substrate.

2. The integrated circuit package assembly of claim 1, wherein the adhesive is an epoxy resin.

3. An integrated circuit (IC) package substrate processing method for enhancing cohesion between an IC and a substrate, the method comprising:
forming a plurality of vias in the substrate;
coating inner walls of the plurality of vias with copper;
filling in the plurality of vias with an adhesive;
coating top and bottom surfaces of the substrate with copper;
coating surfaces of the substrate which are not to be etched with nickel and gold on the copper; and
etching the copper coated on the surfaces of the substrate which are not coated with nickel and gold;
wherein the etched surfaces of the substrate fix the IC to the substrate by the adhesive.

4. The integrated circuit package substrate processing method of claim 3, wherein the adhesive is an epoxy resin.

5. The integrated circuit package substrate processing method of claim 3, wherein the step of forming a plurality of vias in the substrate comprising:
drilling a plurality of vias in the substrate.
